(19) United States
(12) Patent Application Publication
(10) Pub. No.: US 2012/0202300 A1
(43) Pub. Date: Aug. 9, 2012

(54) DIE BONDER INCLUDING AUTOMATIC BOND LINE THICKNESS MEASUREMENT

(75) Inventors: Frank Yu, Taipei (TW); Eric Hsieh, Taipei (TW); Twu Ares, Taipei (TW); Wei-Lung Hsu, Taipei (TW)

(73) Assignee: TEXAS INSTRUMENTS INCORPORATED, Dallas, TX (US)

(21) Appl. No.: 13/020,339

(22) Filed: Feb. 3, 2011

(51) Int. Cl. H01L 21/66; B23K 31/12

(52) U.S. Cl. 438/5; 438/15; 228/4.5; 257/E21.53; 257/E21.528

(57) ABSTRACT

A method for assembling integrated circuit (IC) devices includes dispensing a die attach adhesive onto a surface of a workpiece using a die bonding system, and placing an IC die on the die attach adhesive at surface of the workpiece to form an IC device. A pre-cure bond line thickness (pre-cure BLT) value is automatically optically measured for the die attach adhesive. The IC device is unloaded from the die bonding system after automatically optically measuring. The method can include comparing the pre-cure BLT value to a pre-cure BLT specification range, and if the pre-cure BLT value is outside the pre-cure BLT specification range, adjusting at least one die attach adhesive dispensing parameter based on the pre-cure BLT value for subsequent assembling. The adjusting can be automatic adjusting and the adjustment can be to the Z height parameter of the bond arm.

### FIELD

Disclosed embodiments relate to semiconductor device assembly, more particularly, to the attachment of integrated circuit (IC) die to a receiving substrate using a die attach adhesive.

### BACKGROUND

During the formation of a semiconductor IC device such as a memory device or a logic device, a semiconductor IC die or die stack can be attached to a receiving workpiece (or substrate) such as a die pad of a lead frame, then encapsulated in a resin encapsulation. For example, a quantity of die attach adhesive, for example a thermally and/or electrically conductive epoxy, is dispensed onto a lead frame in a particular pattern which enhances die adhesion, and the die is placed into the adhesive using a measured force. A “scrub” may be employed by moving the die in the X and Y directions relative to the lead frame to remove voids from the adhesive, and to enhance contact between the IC die, the adhesive, and the lead frame.

The quantity of die attach adhesive dispensed onto the lead frame should be sufficient to ensure a strong attachment between the IC die and the lead frame or other receiving workpiece. A deficiency of die attach material can result in the IC die detaching from the lead frame during operation, resulting in failure of the IC device. Excess die attach material can result in adhesive deposits on the circuit side (topside) of the die, which can interfere with attachment of bond wires or damage circuitry on the topside of the IC die.

To insure that the dispensed quantity of die attach adhesive is sufficient but not excessive, a post bond inspection (PBI) process after the IC die has been attached to the workpiece and the die attach adhesive has been cured on a sample basis at a selected measurement interval is used to determine whether the quantity of die attach adhesive is appropriate. During PBI, die attach operations are generally stopped to await the results before continuing die attach operations. In one PBI method, after unloading from the die bonder after bonding is completed, an off-line optical system separate from the die bonder is used to produce a plan view image of the IC die and the workpiece which allows measurement of a die attach fillet to determine if the quantity of dispensed die attach adhesive is sufficient but not excessive. If a width of the fillet is insufficient or the fillet is discontinuous, it is assumed that the quantity of die attach adhesive is insufficient. If the width of the fillet is too great or die attach adhesive is found on the active circuit (topside) of the IC die, an excess of die attach adhesive is assumed.

The measured amount of die attach adhesive between the IC die and the lead frame or other workpiece following cure should thus be within a desired range. If the quantity of die attach adhesive varies from the target value by more than a predetermined value as determined at PBI, the device can be reworked or scrapped. A die bond operator can change the dispensed quantity of die attach adhesive by manually adjusting a dispense time or dispensing pressure used to dispense the die attach adhesive from a syringe that has a reservoir which contains the die attach adhesive.

### SUMMARY

Disclosed embodiments recognize that the current BLT control practice of manual off-line post bond inspection (PBI) measurements on a sampling basis by an operator using a microscope after unloading from the die bonder causes a productivity loss since production is suspended awaiting the PBI results. Moreover, BLT control problems cannot be detected between measurement intervals, resulting in rework or scrap of product assembled between measurement intervals.

Disclosed embodiments add an automatic in-line BLT measurement system that measures a pre-cure bond line thickness (pre-cure BLT) value, comprising an optical sensor that is built into the die bonder system for automatically in-line measuring the pre-cure BLT after attachment of the IC die to a workpiece. As used herein “in-line” refers to the optical measurement performed before the unloading of the IC device from the die bonder. Disclosed embodiments enable a substantial increase in the BLT monitor frequency, including for every IC device in one embodiment, without any productivity loss. In one embodiment, the measured pre-cure BLT value is automatically compared to a pre-cure BLT specification range, and if the pre-cure BLT value is outside the pre-cure BLT specification range, at least one die attach adhesive dispensing parameter can be automatically adjusted based on the pre-cure BLT value for subsequent assembling. For example, the Z (vertical) height parameter setting for the Z translatable bond arm of the die bonder can be moved to change the Z height value of the bond arm relative to the surface of the workpiece (e.g., lead frame, or package substrate).

### BRIEF DESCRIPTION OF THE DRAWINGS

FIG. 1 is a flow chart for a method for assembling integrated circuit (IC) devices including automatic in-line bond line pre-cure BLT measurement in accordance with an example embodiment.

FIG. 2 shows a depiction of first and second optical distance measurements that can be used to obtain the pre-cure BLT value for a die attach adhesive between an IC die and a top surface of a workpiece.

FIG. 3A is a schematic depiction of an example die bonding system including automatic in-line pre-cure BLT measurement and optional pre-cure BLT adjustment for subsequent assemblies based on the measured pre-cure BLT value, according to an example embodiment.

FIG. 3B shows a depiction of a portion of the die bonding system shown in FIG. 3A with the components shown in more detail.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

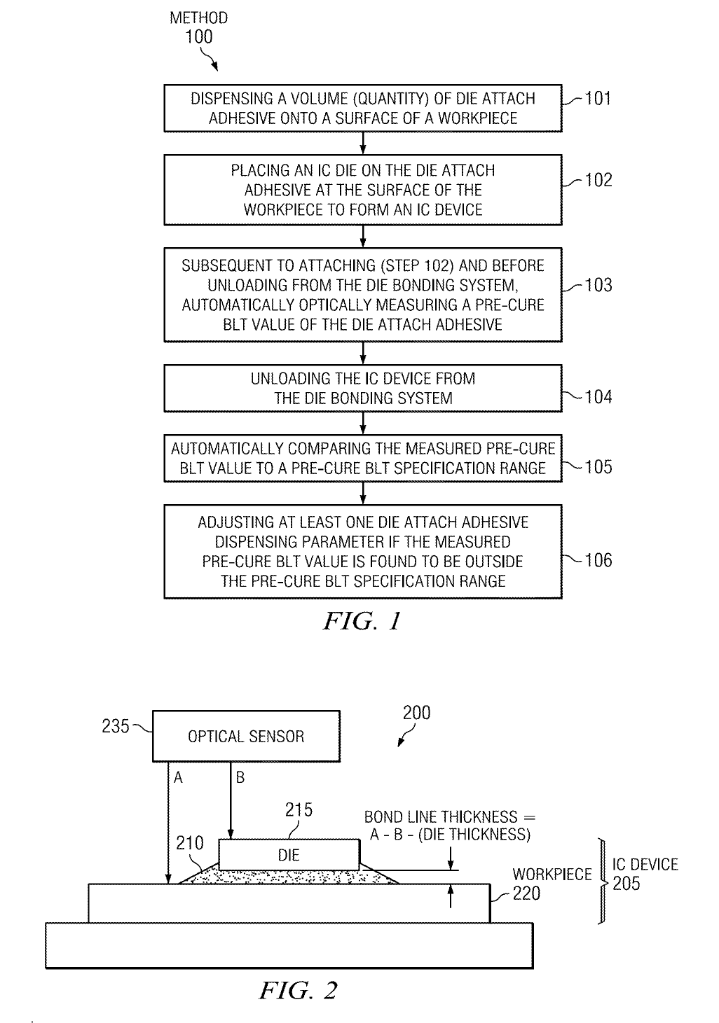

A method 100 for assembling IC devices including automatic in-line BLT measurement in accordance with an example embodiment is shown in the flow chart of FIG. 1. Method 100 begins at step 101 by dispensing a volume (quantity) of die attach adhesive onto a surface of a workpiece, for example a lead frame die pad, polymer or ceramic substrate, an IC die or IC wafer, or an IC die stack, using a die bonding system. Conventional die bonding systems general comprise at least one vertically (Z) translatable bond arm.

The adhesive can be located within, and dispensed from, a container such as a syringe. The adhesive can be dispensed using one or more techniques, such as by applying a controlled, measured (i.e. known) pressure to a plunger, or by increasing the atmospheric pressure within the container using air pressure, etc., for a known duration of time. The die attach adhesive can include conductive and/or dielectric fluid materials such as silver-filled epoxies, aluminum-filled epoxies, unfilled epoxies, polyimides, etc. Both the appropriate dispense pressure and duration of time for a given IC device are generally known and controlled.

Step 102 comprises placing an IC die on the die attach adhesive at the surface of the workpiece to form an IC device. The placing can be circuit side up (e.g., when the IC includes through substrate vias (TSVs)) or flip-chip. A bond arm applies a bonding force onto the IC die. The Z-position setting of the bond arm is a system parameter setting that is controlled by the die bonding system.

Step 103 comprises subsequent to attaching in step 102, and before unloading the IC device from die bonding system, automatically optically measuring a pre-cure BLT value for the die attach adhesive. As known in the art, the pre-cure BLT of the die attach adhesive between the IC die and the workpiece can drift over time due to a number of causes. For example, a viscosity of a die attach adhesive may not be constant across an entire container such as a syringe which is used to dispense the adhesive. This can result from changes to the composition of materials used for die attach adhesive over time. For example, a die attach adhesive can include a resin (liquid carrier) and a filler (solid, e.g., Ag particles) which although intended to be a suspension can settle out or become unevenly mixed within the resin over a period of time. Thus, the viscosity of the die attach adhesive dispensed from a syringe may not be constant through the entire quantity within the syringe, and viscosities across syringes can also vary across lots. Further, while ambient temperature is controlled within a production environments, temperature fluctuations can may also occur which can also affect the viscosity. As known in the art, a fluid generally has a lower viscosity at higher temperatures and a higher viscosity at lower temperatures.

Disclosed die bonding systems include an automatic in-line pre-cure BLT measurement system that comprises and optical sensor and a computer (or processor, along with an optional controller) coupled to the optical sensor. The optical sensor includes a light source, such as a laser or light emitting diode (LED), and a photodetector. In one particular embodiment the optical sensor is an optical distance sensor, such as a laser distance sensor. One example laser distance sensor is a Keyence LK-G32 laser displacement sensor (Keyence Corporation, Elmwood Park, N.J.).

As known in the art of laser sensors, laser displacement sensors are one type of laser distance sensor that provides high accuracy and repeatability for distance measurements. One particular laser displacement sensor that provides highly accurate for distance measurements is based on self-mixing interferometry (SMI). SMI laser sensors make use of the effect that laser light, which is scattered back from a target object and re-enters the laser cavity, interferes with the resonating radiation in the laser cavity and thus influences the output properties of the laser. When the laser is operated not too far above the laser threshold, the response to the back-coupled light is linear, and the resulting output power or frequency variations contain traceable information on the movement or distance of the target object with respect to the sensor. The laser output signal, which contains the information, is collected via a photodetector.

The automatically optically measuring pre-cure BLT to obtain a pre-cure BLT value can comprise using an optical sensor coupled to a computer or processor for a first measurement to obtain a first distance between a reference location and a top of the IC die, and a second measurement to obtain a second distance between the reference location and an exposed portion of the surface of the workpiece. Pre-cure BLT can be automatically calculated, such as by a computer, as the second distance minus the first distance minus a thickness of the IC die. The thickness of the IC die is generally known, and is well controlled, such as set by previous backgrind processing.

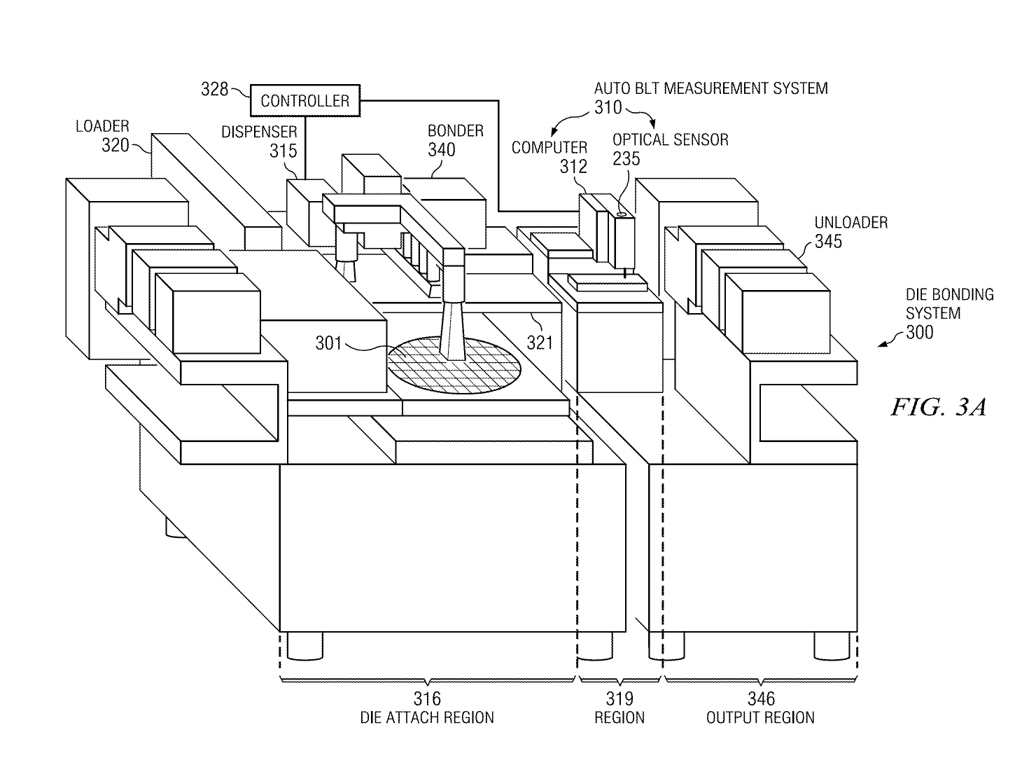

FIG. 2 shows a depiction 200 including an optical sensor 235 shown making a first measurement (A) and second measurement (B) that can be used by a computer or processor (not shown) coupled to the optical sensor to obtain the pre-cure BLT value for the die attach adhesive 210 of an IC device 205. IC device 205 comprises an IC die 215 bonded to a workpiece 220 that is on a support platform. As shown in FIG. 2:

pre-cure BLT=A−B−the thickness of the IC die 210.

Step 104 comprises unloading the IC device from the die bonding system. Step 105 comprises automatically comparing the measured pre-cure BLT value to a pre-cure BLT specification range. If the pre-cure BLT value of the IC device is determined to be out of specification range, the IC device can be reworked. In an alternate process, if the pre-cure BLT value is determined to be out of the specification range, the IC device can be scrapped.

Step 106 comprises adjusting at least one die attach adhesive dispensing parameter if the measured pre-cure BLT value is found to be outside the pre-cure BLT specification range. The adjusted die attach adhesive dispensing parameter can be used for subsequent assembling. The die attach adhesive dispensing parameter can comprise changing a Z height parameter of the bond arm relative to the surface of the workpiece. A lower Z height lowers bond arm relative to bonding surface decreases the pre-cure BLT, and a higher Z height raises the bond arm relative to bonding surface increases the pre-cure BLT. It is also possible to change other die attach dispensing parameters to adjust BLT including air dispensing pressure and dispensing time.

In one embodiment, if the pre-cure BLT value is found to be outside the specification range, the die bonding machine can alarm, and production stopped until a die attach dispensing parameter is changed to correct the pre-cure BLT. In another embodiment, the die attach dispensing parameter can be automatically adjusted using a computer-based system including a controller to automatically correct the pre-cure BLT to maintain a pre-cure BLT specification range. This automatic correction embodiment eliminates productivity loss since there is no need for die bonding operations to be stopped.

Method 100 thus allows control of the pre-cure BLT value in-line during production which allows control of the post-cure BLT value based on a correlation between pre-cure BLT and post-cure BLT. The method can include automatically maintaining a pre-cure BLT specification range without any productivity loss. Furthermore, automatic adjustment of the pre-cure BLT using a computer-based system including a controller will likely be more precise and faster than conventional manual adjustments by an operator or technician, and therefore less costly. In addition, the incidence of out of specification BLT values are significantly reduced because in a conventional control process that includes only a sample off-line post bonding BLT measurement an incorrect BLT value may only be recognized after a plurality of IC devices receive the wrong BLT value, adding to rework and/or scrap.

Disclosed embodiments recognize that the BLT value can change between pre-cure and post cure. For example, the amount of the thickness change can depend on die attach material characteristics, handling, and time after dispensing of the die attach adhesive. Disclosed methods can also include curing the die attach adhesive from the uncured state after unloading from the die bonder, measuring at least one cured BLT value for a selected one of the IC devices from an assembly lot comprising a plurality of IC devices, and determining (or verifying) a correlation between the pre-cure BLT value and cured BLT value. This embodiment can also comprise adjusting at least one die attach adhesive dispensing parameter for subsequent assembling based on the correlation.

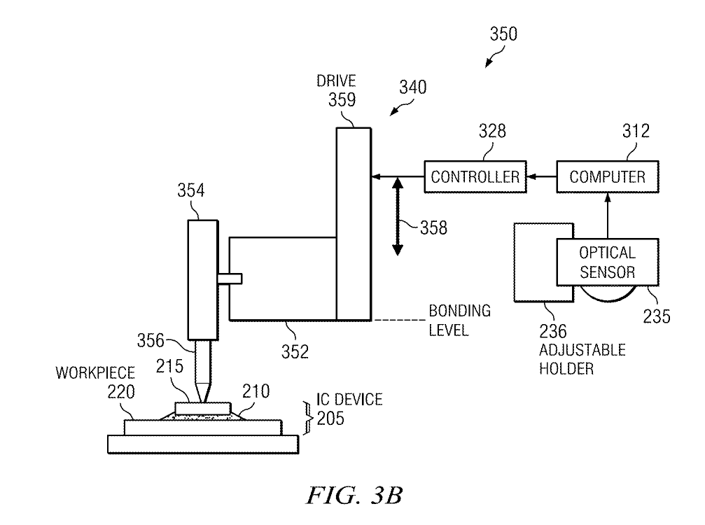

FIG. 3A is a schematic depiction of an example die bonding system 300 including an automatic pre-cure BLT measurement system 310, according to an example embodiment. Automatic pre-cure BLT measurement system 310 includes an optical sensor 235 and computer (or processor) 312. System 300 includes a loader 320 for placing at least one workpiece (e.g., a lead frame sheet) onto a surface of an x-y table (not shown) that is in die attach region 316 and a dispenser (e.g., syringe) 315 in a die attach region 316 for dispensing a die attach adhesive onto a surface of the workpiece. A feeder 321 is for placing an IC die or die stack, such as from the singulated probed wafer 301 shown on the x-y table in a position to receive the die attach adhesive from dispenser 315. A die bonding apparatus 340 includes at least one vertically (Z) translatable bond arm for bonding the IC die or stack of IC die to the workpiece to form an IC device. An unloader 345 is in an output region 346 of system 300 for unloading the IC device after attachment.

A controller 328 is shown coupled between the computer 312 associated with automatic pre-cure BLT measurement system 310 and the dispenser 315. The coupling can be wired or wireless. Although shown as separate blocks, computer 312 can instead comprise a computer system which can include a processor that functions as a controller.

The pre-cure BLT measuring system 310 in region 319 of system 300 is between the die attach region 316 and the output region 346. As described above, optical sensor 235 can comprise a laser or LED-based sensor for interrogating the IC device to obtain optical data related to the pre-cure die attach adhesive between the IC die and the workpiece, while computer 312 includes software for determining a pre-cure BLT value of the IC device from the optical data. The optical data can be provided to the computer 312 via a data bus, for example using a cable, or wirelessly.

FIG. 3B shows a depiction of a portion 350 of system 300 shown in FIG. 3A with the die bonding apparatus 340 shown in more detail. Portion 350 of die bonding apparatus 340 is shown in a side view while performing bonding. Die bonding apparatus 340 generally comprises two main components, namely a bond arm support 352 and a bond arm 354. The bond arm 354 is linked to the bond arm support 352 via a sliding mechanism, so that the bond arm 354 is movable relative to the bond arm support 352. A collet 356 is mounted onto the bond arm 354 for holding IC die or stacked IC die 215, usually by utilizing vacuum suction, and bonding them onto bonding surfaces.

The bond arm support 352 is driven by motor drive 359 to undergo up-and-down Z motion 358 to move the bond arm 354 and collet 356 towards or away from a bonding surface. Controller 328 is shown coupled to motor drive 359. Optical sensor 235 is shown including an adjustable holder 236 for holding and moving the optical sensor 235 to provide at least first and second interrogated locations on the IC device during interrogating, such as locations A and B shown in FIG. 2.

As described above, optical sensor 235 automatically provides a first measurement to obtain a first distance between a reference to a top of the IC die, and a second measurement to obtain a second distance between the reference to an exposed portion of the surface of the workpiece. A computer (or processor) 312 that has software computes the pre-cure BLT value from the optical data provided by the optical sensor 235 receives these measurements and calculates the pre-cure BLT value. Computer 312 is coupled to controller 328 which sends a control signal to drive 359 to automatically adjust the Z height parameter of the bond arm 354 relative to the surface of the workpiece 220. As described above, if the computer 312 determines the pre-cure BLT value of the IC device is outside a pre-cure BLT specification range, the controller 328 can send a control signal that automatically changes a Z height parameter setting of the bond arm relative to the surface of said workpiece to bring the pre-cure BLT value for subsequent assemblies into the specification range.

Disclosed automatic in-line pre-cure BLT measurements provide a better % Gauge Repeatability and Reproducibility (GRR) as compared to conventional manual measurements. Disclosed automatic pre-cure BLT measurements can also monitor the IC assembly in real-time without shutting down the die bonder machine, and thus avoid the product loss caused by conventional manual handling associated with conventional manual measurements. Therefore, disclosed embodiments provide improve productivity, as well as cost savings from improved quality control that reduces rework and/or scrap of product.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method for assembling integrated circuit (IC) devices, comprising:
dispensing a die attach adhesive onto a surface of a workpiece using a die bonding system;
placing an IC die on said die attach adhesive at said surface of said workpiece to form an IC device;
automatically optically measuring a pre-cure bond line thickness (pre-cure BLT) value for said die attach adhesive for said IC device while said die attach adhesive is in a uncured state, and
unloading said IC device from said die bonding system after said automatically optically measuring.

2. The method of claim 1, further comprising:
comparing said pre-cure BLT value to a pre-cure BLT specification range, and
if said pre-cure BLT value is outside said pre-cure BLT specification range, adjusting at least one die attach adhesive dispensing parameter based on said pre-cure BLT value for subsequent assembling.

3. The method of claim 1, further comprising:
curing said die attach adhesive from said uncured state after said unloading;
measuring at least one cured BLT value for a selected one of said IC devices from an assembly lot comprising a plurality of said IC devices, and
determining a correlation between said pre-cure BLT value and said cured BLT value.

4. The method of claim 3, further comprising adjusting at least one die attach adhesive dispensing parameter for subsequent assembling based on said correlation.

5. The method of claim 4, wherein said adjusting comprises automatically adjusting.

6. The method of claim 5, wherein said die bonding system includes at least one vertically (Z direction) translatable bond arm and said adjusting comprises changing a Z height parameter of said bond arm relative to said surface of said workpiece.

7. The method of claim 1, wherein said die bonding system includes a BLT measurement system comprising an optical sensor including a light source and a photodetector, and a computer coupled to said optical sensor.

8. The method of claim 7, wherein said light source comprises a laser or light emitting diode (LED).

9. The method of claim 8, wherein said optical sensor comprises a laser displacement sensor.

10. The method of claim 7, wherein said automatically optically measuring comprises a first measurement to obtain a first distance between a reference and a top of said IC die, and a second measurement to obtain a second distance between said reference and an exposed portion of said surface of said workpiece, wherein said pre-cure BLT value is calculated as said second distance minus said first distance minus a thickness of said IC die.

11. A method for assembling integrated circuit (IC) devices, comprising:
dispensing a die attach adhesive onto a surface of a workpiece using a die bonding system that includes at least one vertically (Z direction) translatable bond arm;
placing an integrated circuit (IC) die on said die attach adhesive at surface of said workpiece to form an IC device;
automatically optically measuring a pre-cure bond line thickness (pre-cure BLT) value for said die attach adhesive while said die attach adhesive is in a uncured state using a laser or light emitting diode (LED)-based sensor;
comparing said pre-cure BLT value to a pre-cure BLT specification range;
wherein if said pre-cure BLT value is outside said specification range, adjusting a Z height parameter of said translatable bond arm relative to said surface of said workpiece based on said pre-cure BLT value for subsequent assembling, and
unloading said IC device from said die bonding system after said automatically optically measuring.

12. The method of claim 11, wherein said adjusting comprises automatically adjusting.

13. The method of claim 11, wherein said laser or light emitting diode (LED)-based sensor comprises a self-mixing interferometry (SMI)-based displacement sensor.

14. A die bonding system, comprising:
a dispenser in a die attach region for dispensing a die attach adhesive onto a surface of a workpiece;
a loader for placing an integrated circuit (IC) die onto said die attach adhesive on said surface of said workpiece;
a bond head including at least one vertically (Z direction) translatable bond arm for bonding said IC die to said workpiece to form an IC device;
an unloader in an output region for unloading said IC device;
an automatic pre cure bond line thickness (pre-cure BLT) measuring system comprising:
an optical sensor including a light source and a photodetector, and a computer coupled to said optical sensor for interrogating said IC device while said IC device is in a region of said die bonding system between said die attach region and said output region while said die attach adhesive is in a uncured state to obtain optical data, and
wherein said computer includes computer software coupled to said optical sensor for automatically determining a pre-cure BLT value from said optical data.

15. The system of claim 14, wherein said optical sensor comprises a laser or light emitting diode (LED)-based sensor.

16. The system of claim 15, wherein said laser or light emitting diode (LED)-based sensor comprises a self-mixing interferometry (SMI)-based displacement sensor.

17. The system of claim 14, further comprising a controller that is communicably coupled to said computer and to a structure for moving said bond arm in said Z direction,
wherein if said computer determines said pre-cure BLT value of said IC device is outside a pre-cure BLT specification range, said controller sends a control signal that triggers an automatic change to a Z height parameter setting of said bond arm relative to said surface of said workpiece to bring said pre-cure BLT value for subsequent assemblies into said pre-cure BLT specification range.

18. The system of claim 14, further comprising an adjustable holder for holding and moving said optical sensor, movement of said optical sensor providing at least first and second interrogated locations on said IC device during said interrogating.
